(19) United States
(12) Patent Application Publication
(10) Pub. No.: US 2022/0254655 A1
(43) Pub. Date: Aug. 11, 2022

(54) POWER MODULE FOR THE OPERATION OF AN ELECTRIC VEHICLE DRIVE WITH DIRECT COOLING OF THE POWER SEMICONDUCTOR

(71) Applicant: ZF Friedrichshafen AG, Friedrichshafen (DE)

(72) Inventors: Ake Ewald, Bayreuth (DE); Stefan Hain, Speichersdorf (DE)

(73) Assignee: ZF Friedrichshafen AG, Friedrichshafen (DE)

(21) Appl. No.: 17/668,864

(22) Filed: Feb. 10, 2022

(30) Foreign Application Priority Data
Feb. 10, 2021 (DE) 102021201263.9

(51) Int. Cl. H01L 21/48; H05K 7/20; H01L 23/473; H01L 23/42; B33Y 80/00; B33Y 70/00; B33Y 10/00

(52) U.S. Cl. CPC H01L 21/4882; H05K 7/20872; H05K 7/20927; B33Y 10/00; H01L 23/42; B33Y 80/00; B33Y 70/00; H01L 23/473

(57) ABSTRACT

A power module for operating an electric vehicle drive may include one or more of the following: a plurality of semiconductor switching elements; a substrate; and a set of drive electronics. A cooling structure with a plurality of cooling channels may be included to cool certain portions of the device. Each semiconductor switching element of the plurality of semiconductor switching elements may be potted with a potting compound, where the cooling structure is attached to the potting compound via a structure formed with additive manufacturing. A method for forming the power module utilizing such additive manufacturing is also contemplated.

### RELATED APPLICATION

This application claims the benefit of, and priority to, German Patent Application DE 10 2021 201 263.9, filed Feb. 10, 2021, which is incorporated by reference herein in its entirety.

### TECHNICAL FIELD

The present invention relates to the field of electric mobility, in particular of power modules for the operation of an electric drive for a vehicle.

### BACKGROUND

Power modules, in particular integrated power modules, are being increasingly applied in motor vehicles. Power modules of this sort are, for example, employed in DC/AC inverters whose purpose is to supply multiphase alternating currents to machines such as electric motors. Direct current generated by means of a DC energy source, such as a battery, is converted here into a multiphase alternating current. The power modules are based on power semiconductors, in particular transistors such as IGBTs, MOSFETs and HEMTs. Further fields of application include DC/DC converters and AC/DC rectifiers, and transformers.

Power switches which are used in a bridge circuit are usually formed from the power semiconductors. A frequent example is provided by what are known as halfbridges, which comprise a highside component and a lowside component. The highside and lowside components each comprise one or a plurality of power switches, namely highside power switches and lowside power switches. Through the controlled switching of the highside and lowside power switches, the direction of the current generated at the output of the power module (output current) can be changed, within a very short cycle time, between a positive current direction and a negative current direction. This enables what is known as pulsewidth modulation in order, in the case of a DC/AC inverter, that an alternating current is generated on the basis of a direct current fed in at an input side of the power module.

It is advantageous for all these applications for the switching time of the power switches used to be sufficiently short. Thanks to the advances in the field of power semiconductors, short switching times can be realized with what are known as wide bandgap semiconductors such as SiC and GaN.

The controlled switching of the power switches is performed and implemented by drive electronics. The drive electronics usually comprise a controller component to generate a control signal on the basis of an operating state of the electric vehicle drive and/or of the power module, and a driver component in communication with the controller component for driving the power switches on the basis of the control signal.

The semiconductor switching elements are subjected to high currents when the power module is operating. A large quantity of heat is thereby generated in the semiconductor switching elements, and this must be dissipated in order to avoid overheating the semiconductor switching elements and an associated impairment of the power module.

A heatsink is provided to the power modules known to date from the prior art to cool the semiconductor switching elements; it is in contact with the substrate to which the semiconductor switching elements are attached. The heatsink usually comprises a cooling plate that is in direct contact with the substrate. The heatsink also comprises a cooling structure, for example a pin-fin structure, with a plurality of fins, between which cooling channels through which a cooling fluid (e.g. water) flows are formed. The cooling plate draws heat from the semiconductor switching elements via the substrate. This withdrawn heat is distributed over the cooling structure, and a heat exchange takes place between the cooling fluid in the cooling structure, and thereby also the semiconductor switching elements.

The known power modules are, however, subject to several restrictions related to manufacture and assembly. A pressing method is conventionally required to bond the substrate, together with the semiconductor switching elements, to the cooling plate. A minimum thickness must, however, be maintained for the cooling plate in order not to deform or even destroy the cooling structure when pressing into place, and at the same time to ensure a secure bond between the substrate and the cooling plate. This results in a large installation space and laborious manufacture.

### BRIEF DESCRIPTION OF THE DRAWINGS

FIG. 1 shows a schematic illustration of a known power module;

FIG. 2 shows a schematic illustration of a power module that is manufactured by means of the method according to one embodiment;

FIG. 3 shows a schematic illustration of a power module that is manufactured by means of a method according to a further embodiment;

FIGS. 4 A-C show a schematic illustration of the method for manufacture of the power module in FIG. 2; and

FIGS. 5 A-D show a schematic illustration of the method for manufacture of the power module in FIG. 3.

### DETAILED DESCRIPTION

In view of the background above, the present embodiments are described for simplifying the manufacture of a power module and, at the same time, reducing the installation space of the power module.

In this context, in one aspect, the power module serves for the operation of an electric drive of a vehicle, in particular of an electric vehicle and/or of a hybrid vehicle. The power module is preferably installed in a DC/AC inverter. The power module serves in particular to supply current to an electric machine, for example an electric motor and/or a generator. A DC/AC inverter is used to generate a multiphase alternating current from a direct current generated by means of a DC voltage of an energy source such as a battery.

In one aspect, the power module comprises a plurality of semiconductor switching elements (or power switches). These semiconductor-based power switches are used to generate an alternating current at the output side by driving the individual semiconductor switching elements on the basis of the direct current fed in at the input side. The drive of the semiconductor switching elements is made by means of the drive electronics that comprise one or a plurality of circuit boards to which a large number of electronic components are attached. The drive electronics preferably comprise a controller component to generate a control signal on the basis of an operating state of the power module, and a driver component for driving the semiconductor switching elements on the basis of the control signal. The drive is preferably based on what is known as pulse-width modulation, by means of which a sinusoidal profile is provided for the respective phase current of the output-side alternating current.

In one aspect, the multiple semiconductor switching elements preferably form a bridge circuit arrangement that can comprise one or a plurality of bridge circuits (such as halfbridges). Each bridge circuit, or halfbridge, comprises one or a plurality of highside semiconductor switching elements (HS switches) connected in parallel, and one or a plurality of low-side semiconductor switching elements (LS switches) connected in parallel. The HS switch or switches is/are connected in series with the LS switch or switches. Each halfbridge is assigned in the inverter to one current phase of the multiphase alternating current (output current). The individual semiconductor switching elements can be designed as IGBTs, MOSFETs, or HEMTs. The semiconductor material on which the respective semiconductor element is based preferably comprises what is known as a wide bandgap semiconductor such as silicon carbide (SiC) or gallium nitride (GaN), but can alternatively or in addition comprise silicon.

In one aspect, the power module comprises a substrate for attachment of the semiconductor switching elements. The substrate is, preferably, a direct bonded copper (DBC), and comprises a first metal plate, a second metal plate, and an insulating plate arranged between the first metal plate and the second metal plate. The metal plates can be made of copper, while the insulating plate can be formed of ceramic.

It is possible, for the purpose of cooling the power switches and other electronic components in the power module, to provide a heatsink to which the semiconductor switching elements are thermally coupled. The heatsink comprises a cooling structure that has one or a plurality of cooling channels through which a cooling fluid can flow.

In one aspect, the semiconductor switching elements are attached to the first metal plate to fabricate the power module according to the invention. The semiconductor switching elements are then cast with a potting compound preferably comprising a plastic, using a casting method. The cooling structure is then formed on the potting compound by means of additive manufacture. This measure ensures a simplified manufacturing process of the power module, and also reduces the installation space of the power module in comparison with systems known to date.

According to one embodiment, the cooling structure is formed directly on the second metal plate of the substrate by means of the additive manufacture. In this case, the second metal plate that faces away from the potting compound serves as the base plate for the additive manufacture, in particular for the three-dimensional printing method. In this embodiment, a cooling plate which in the power modules known to date is in direct contact with the substrate, and under which the cooling structure is attached, can advantageously be omitted. The power module according to the invention therefore saves space and is easy to manufacture, and thus also comparatively economical.

According to a further embodiment, the cooling plate is first attached to the second metal plate, and the cooling structure is then formed directly by means of additive manufacture on a side of the cooling plate that faces away from the potting compound. In this case, the cooling plate, which is preferably bonded to the second metal plate by sintering, serves as the base plate for the additive manufacture (e.g. the three-dimensional printing method). Because the cooling plate is first brought into contact with the potting compound without the cooling structure, and only after that is the cooling structure additively manufactured on the cooling plate, a minimum thickness for the cooling plate does not have to be maintained, in contrast to the power modules known to date. The cooling plate can therefore be chosen to be significantly thinner than in the power modules known to date. This reduces the installation space, simplifies the manufacture, and reduces the costs of the power module.

Certain embodiments are now described by way of example, and with reference to the appended drawings/figures. Identical reference signs in the figures indicate referenced components that are identical or functionally similar.

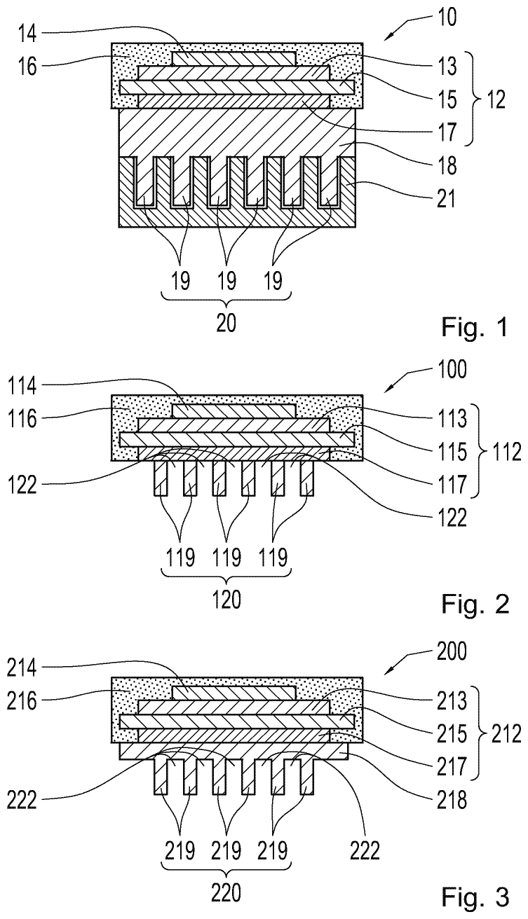

FIG. 1 shows a power module 10 known from the prior art. The power module 10 comprises a plurality of semiconductor switching elements 14 (which are illustrated in simplified form in FIG. 1), a substrate 12 comprising a first metal plate 13, a second metal plate 17, and an insulating plate 15 arranged between the first metal plate 13 and the second metal plate 17. The semiconductor switching elements 14 are attached to the first metal plate 13. The semiconductor switching elements 14 are potted and covered by a potting compound 16 to protect against external environmental effects.

The potting compound 16, which henceforth encloses the semiconductor switching elements 14 and the substrate 12, is then brought into contact with a cooling plate 18. A cooling structure 20 that comprises a plurality of fins 19 extends along an underside of the cooling plate 18. In order for this pin-fin structure not to be excessively stressed when bonding the potting compound 16 to the cooling plate 18, a counter-mold 21 with a plurality of intermediate spaces corresponding to the fins 19 is used to accommodate the underside of the cooling structure 20.

The manufacture of the known power module 10 is therefore laborious. A minimum thickness of the cooling plate 18 must moreover be maintained in order to ensure a secure bond between the potting compound 16 and the cooling plate 18, whilst at the same time protecting the pin-fin structure. The known power module 10 therefore must have a relatively large installation space.

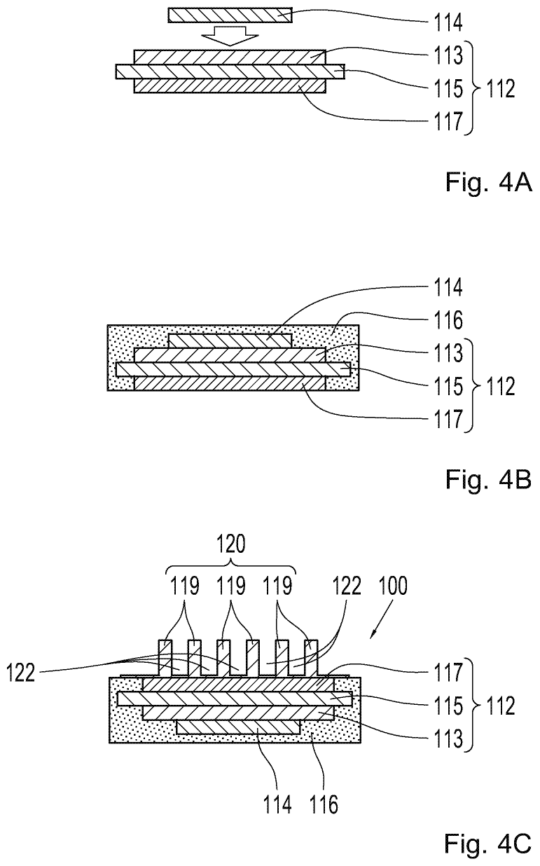

FIG. 2 shows schematically a power module 100 that is manufactured by means of a method according to one embodiment. The manufacturing method is shown schematically in FIGS. 4A-C. The semiconductor switching elements 114 are first attached to the first metal plate 113 of the substrate 112 as shown in FIG. 4A. The semiconductor switching elements 114 are then potted and covered by the potting compound 116, preferably comprising a plastic, by means of a casting method as can be seen in FIG. 4B. The cooling structure 120 is then fabricated directly on the second metal plate 117 of the substrate by means of the additive manufacturing process, as shown in FIG. 4C. In this case the second metal plate 117 that faces away from the potting compound 116 serves as a base plate for the additive manufacture, in particular for the three-dimensional printing method in which the form of the cooling structure 120 that is to be provided, here, by way of example, comprises a plurality of fins 119. Cooling channels 122 through which the cooling fluid will flow form between the fins 119. In this embodiment, a cooling plate, which is essential for reasons of structure and stability in the known power module 10 of FIG. 1, can advantageously be omitted. The power module 100 according to the invention therefore saves space and is easy to manufacture, and therefore also comparatively economical.

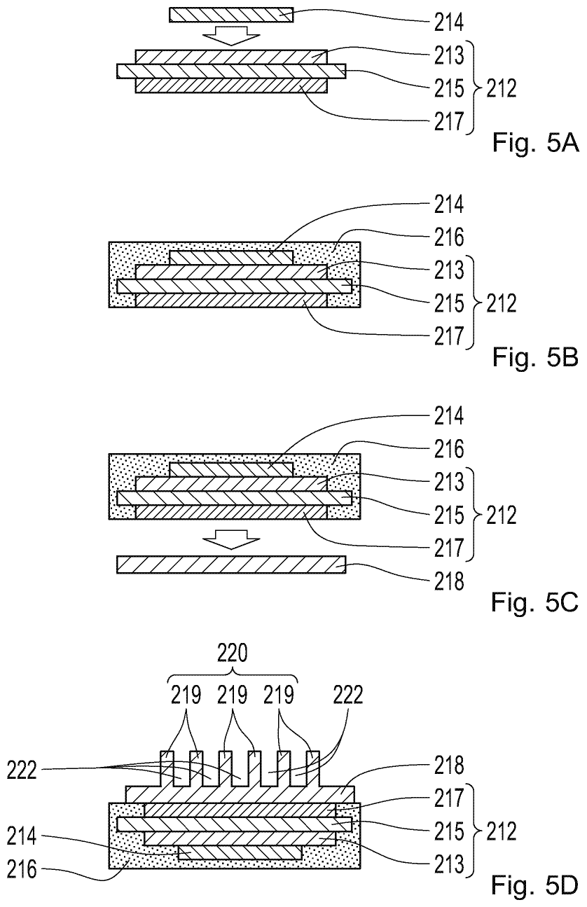

FIG. 3 shows schematically a power module 200 that is manufactured with a method according to a further embodiment. The manufacturing method is shown schematically in FIGS. 5 A-D. The semiconductor switching elements 214 are first attached to the first metal plate 213 of the substrate 212 as shown in FIG. 5A. The semiconductor switching elements 214 are then potted and covered by the potting compound 216, preferably comprising a plastic, by means of a casting method as can be seen in FIG. 5B. The first two manufacturing steps are therefore identical here to those in the method shown schematically in FIGS. 4 A-C.

The cooling plate 218 is then bonded directly to the second metal plate 217, as can be seen in FIG. 5C. This is preferably done by sintering. The cooling structure 220 is finally formed directly on a side of the cooling plate 218 that faces away from the potting compound 216 by means of the additive manufacturing. In this case, the cooling plate 218 serves as the base plate for the additive manufacturing (e.g. the three-dimensional printing method). Here again, the cooling structure 220 can advantageously comprise multiple fins 219 that define multiple cooling channels 222 through which the cooling fluid can flow. Because the cooling plate 218 is first brought into contact with the potting compound without the cooling structure 220, and only after that is the cooling structure 220 additively manufactured on the cooling plate 218, a minimum thickness for the cooling plate 218 does not have to be maintained, in contrast to the power modules 10 known to date. The cooling plate 218 can therefore be chosen to be significantly thinner than in the power modules 10 known to date. This reduces the installation space, simplifies the manufacture, and reduces the costs of the power module 200.

A further advantage that results for the manufacturing method according to the two methods shown in FIGS. 4 A-C and FIGS. 5 A-D, is that the countermould 21 which would otherwise be essential to accommodate the cooling structure 20 and to maintain its mechanical stability, can be omitted. This additionally simplifies the manufacture of the power module 100, 200, and reduces its costs.

### REFERENCE DESIGNATIONS

10, 100, 200 Power module
12, 112, 212 Substrate
13, 113, 213 First metal plate
14, 114, 214 Semiconductor switching elements
15, 115, 215 Second metal plate
16, 116, 216 Potting compound
18, 118, 218 Cooling plate
19, 119, 219 Fins
20, 120, 220 Cooling structure
21 Countermould
122, 222 Cooling channels

We claim:

1. A method for manufacturing a power module, comprising:
attaching a set of semiconductor switching elements to a first metal plate;
potting the set of semiconductor switching elements with a potting compound; and
forming a cooling structure on the potting compound utilizing additive manufacturing.

2. The method of claim 1, wherein the power module includes a plurality the set of semiconductor switching elements, a substrate, and set of drive electronics,
wherein the substrate comprises an insulating plate between a first metal plate and a second metal plate,
wherein the semiconductor switching elements are switchable with the set of drive electronics in such a way that the semiconductor switching elements allow through or interrupt a drain-source current in order to convert a direct current fed on an input side to the power module into an alternating current on an output side of the power module, and
wherein the power module further comprises the cooling structure with a plurality of cooling channels through which a cooling fluid flows.

3. The method according to claim 2, further comprising forming the cooling structure directly on the second metal plate of the substrate by utilizing additive manufacturing.

4. The method according to claim 2, wherein a cooling plate is first attached to the second metal plate, and wherein the cooling structure is then formed directly by utilizing additive manufacturing on a side of the cooling plate that faces away from the potting compound.

5. The method according to claim 1, wherein the cooling structure is formed of at least one of a copper material, an aluminum material, and a ferrous material.

6. The method according to claim 1, wherein the cooling structure comprises a plurality of fins.

7. The method according to claim 1, wherein the step of additive manufacturing includes a three-dimensional printing method.

8. A power module for operating an electric vehicle drive, the power module comprising:
a plurality of semiconductor switching elements;
a substrate;
a set of drive electronics,
wherein the substrate comprises an insulating plate between a first metal plate and a second metal plate,
wherein the plurality of semiconductor switching elements can be switched by utilizing the set of drive electronics in such a way that the semiconductor switching elements allow through or interrupt a drain-source current in order to convert a direct current fed on an input side of the power module into an alternating current on an output side of the power module; and
a cooling structure with a plurality of cooling channels configured to receive a flow of a cooling fluid,
wherein each semiconductor switching element of the plurality of semiconductor switching elements is attached to the first metal plate,
wherein each semiconductor switching element of the plurality of semiconductor switching elements is potted with a potting compound, and
wherein the cooling structure is attached to the potting compound via a structure formed with additive manufacturing.

9. The power module according to claim 8, wherein the cooling structure is formed directly on the second metal plate by utilizing the additive manufacture.

10. The power module according to claim 8, wherein a cooling plate is attached between the second metal plate and the cooling structure.

11. The power module according to claim 8, wherein the cooling structure is formed of a material including at least one fo a copper material, an aluminum material, and a ferrous material.

12. An inverter comprising the power module according to claim 7.
